(19) United States
(12) Patent Application Publication
(10) Pub. No.: US 2008/0162853 A1
(43) Pub. Date: Jul. 3, 2008

(54) Memory systems having a plurality of memories and memory access methods thereof

(75) Inventors: Sung-Kook Bang, Seoul (KR); Jeon-Taek Im, Gyeonggi-do (KR)

Correspondence Address: MYERS BIGEL SIBLEY & SAJOVEC, PO BOX 37428, RALEIGH, NC, 27627, US

(73) Assignee: SAMSUNG ELECTRONICS CO., LTD.

(21) Appl. No.: 11/796,991

(22) Filed: Apr. 30, 2007

(30) Foreign Application Priority Data
Dec. 29, 2006 (KR) 2006-137626

(51) Int. Cl. G11C 8/18; G06F 13/00

(52) U.S. Cl. 711/167

(57) ABSTRACT

A memory system includes a plurality of memories and a controller configured to control the memories and to access each of the memories using timing information respectively associated with each of the memories.

### CROSS-REFERENCE TO RELATED APPLICATIONS

This U.S. non-provisional patent application claims priority under 35 U.S.C. §119 to Korean Patent Application No. 10-2006-0137626, filed on Dec. 29, 2006, the entire contents of which are hereby incorporated herein by reference.

### BACKGROUND OF THE INVENTION

The present invention disclosed herein relates generally to memory systems, and, more particularly, to memory systems having a plurality of memories and memory access methods.

FIG. 1 illustrates a conventional memory system 100. Referring to FIG. 1, the memory system 100 includes a controller 120 and NAND flash memories 140, 160, and 180. The controller 120 controls the NAND flash memories 140, 160, and 180 through a common bus.

The controller 120 receives ready and busy output (R/nB) signals from the NAND flash memories 140, 160, and 180 to access the NAND flash memories 140, 160, and 180. Here, the R/nB signals are signals indicating the operational statuses of the NAND flash memories 140, 160, and 180, respectively.

Generally, an R/nB signal is generated based on the timing characteristics of a NAND flash memory such as a read time tR, a programming time tPROG, and a deletion time tBERS. The read time tR is a time necessary for loading data from a memory cell (not shown) to a page register (not shown), the programming time tPROG is a time necessary for loading data from a page register to a memory cell, and the deletion time tBERS is a time necessary for deleting data from memory cells in units of a block. Undesirably, the timing characteristics of the NAND flash memories 140, 160, and 180 are generally not constant due to variations or limitations of manufacturing processes.

For this reason, the NAND flash memories 140, 160, and 180 of the conventional memory system 100 may not be efficiently accessed.

This problem will now be described using a reading operation as an example. In the following description, it is assumed that the read time tR of the NAND flash memory 140 (hereinafter, referred to as a first NAND flash memory) is 59 μs, the read time tR of the NAND flash memory 160 (hereinafter, referred to as a second NAND flash memory) is 49 μs, and the read time tR of the NAND flash memory 180 (hereinafter, referred to as a third NAND flash memory) is 52 μs. When the controller 120 sends a read command to each of the NAND flash memories 140, 160, and 180, each of the NAND flash memories 140, 160, and 180 loads data from a memory cell to a register in response to the read command. Here, because the second NAND flash memory 160 has the shortest read time tR, the second NAND flash memory 160 loads data most rapidly. However, after that, the second NAND flash memory 160 cannot perform any other operation until data loading of the first NAND flash memory 140 is completed. Similarly, the third NAND flash memory 180 cannot perform any other operation after it loads data until the data loading of the first NAND flash memory 140 is completed.

In the conventional memory system 100, an R/nB signal is used to access the NAND flash memories 140, 160, and 180. However, as described above, the NAND flash memories 140, 160, and 180 may not be efficiently accessed. This problem may be more significant when the memory system 100 has more NAND flash memories.

### SUMMARY

According to some embodiments of the present invention, a memory system includes a plurality of memories and a controller configured to control the memories and to access each of the memories using timing information respectively associated with each of the memories.

In other embodiments, the memories comprise registers that store the timing information, respectively.

In still other embodiments, the memories share a common bus line.

In still other embodiments, the controller accesses the memories using the timing information read from the registers in an initializing operation.

In still other embodiments, the memories are configured to not generate R/nB (ready and busy output) signals.

In still other embodiments, the memories are nonvolatile memories.

In still other embodiments, the memories are NAND flash memories.

In still other embodiments, the timing information comprises a read time tR, a programming time tPROG, and a deletion time tBERS.

In still other embodiments, the registers are respectively defined using zero blocks of the memories that store basic information of the memories.

In still other embodiments, the controller comprises a storage that stores the timing information read from the registers of the memories.

In still other embodiments, the controller accesses the memories using the timing information stored in the storage.

In still other embodiments, the memory system is a multi-chip memory system or a one-chip memory system.

In further embodiments of the present invention, a memory system includes a plurality of memories and a controller configured to control the memories and to store timing information respectively associated with each of the memories that is used to access the memories.

In still further embodiments, the controller comprises a register that stores the timing information.

In still further embodiments, the memories share a common bus line.

In still further embodiments, the controller is configured to measure the timing information using R/nB signals received from the memories and to store the measured timing information in the register in an initializing operation.

In still further embodiments, the controller is configured to ignore R/nB signals transmitted from the memories after the timing information is stored in the register of the controller.

In still further embodiments, the memories are nonvolatile memories.

In still further embodiments, the memories are NAND flash memories.

In still further embodiments, the timing information comprises a read time tR, a programming time tPROG, and a deletion time tBERS.

In still further embodiments, the memory system is a multi-chip memory system or a one-chip memory system.

In other embodiments of the present invention, a method of accessing a memory system that includes a plurality of memories and a controller that controls the memories includes measuring timing information associated with each of the memories, storing the measured timing information and accessing the memories using the stored timing information.

In still other embodiments, measuring of the timing information comprises reading timing information stored in the memories.

In still other embodiments, the timing information comprises information stored in the memories when the memories are manufactured.

In still other embodiments, the controller comprises a timing information register configured to store the measured timing information.

In still other embodiments, the memories are nonvolatile memories.

In still other embodiments, the memories are NAND flash memories.

In still other embodiments, the timing information comprises a read time tR, a programming time tPROG, and a deletion time tBERS.

In still other embodiments, measuring the timing information comprises operating the controller to measure the timing information using R/nB signals received from the memories in an initializing operation.

In still other embodiments, storing the measured timing information comprises storing the measured timing information in a timing information register in the controller.

In still other embodiments, after storing the measured timing information in the timing information register, R/nB signals transmitted from the memories are ignored and the memories are accessed using the measured timing information stored in the timing information register.

In still other embodiments, the memory system is a memory card.

### BRIEF DESCRIPTION OF THE DRAWINGS

Other features of the present invention will be more readily understood from the following detailed description of exemplary embodiments thereof when read in conjunction with the accompanying drawings, in which:

FIG. 1 illustrates a conventional memory system having a plurality of memories;

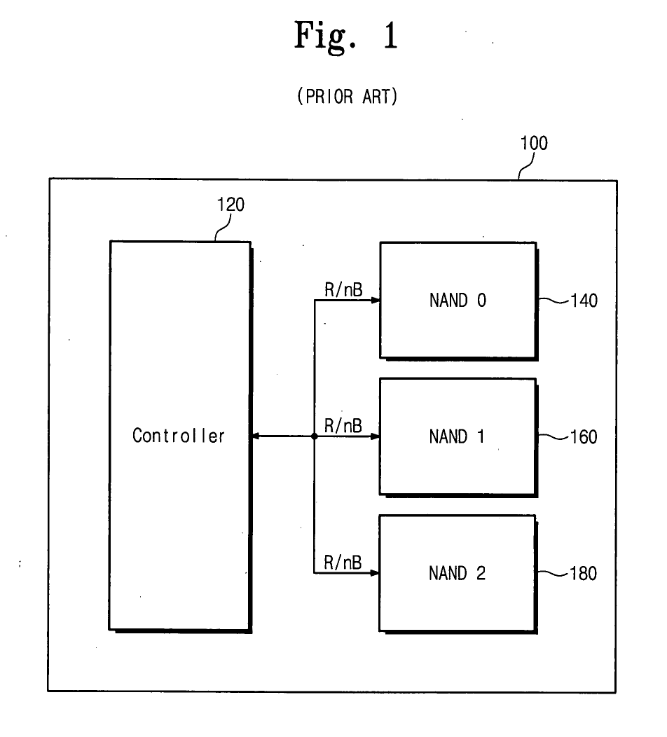

FIG. 2 illustrates a memory system having a plurality of memories according to some embodiments of the present invention;

FIG. 3 illustrates a memory system having a plurality of memories according to further embodiments of the present invention; and

FIG. 4 illustrates a method of accessing a plurality of memories of a memory system according to some embodiments of the present invention.

### DETAILED DESCRIPTION

The invention now will be described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. Like reference numerals refer to like elements throughout the description of the figures.

It will be understood that when an element is referred to as being “connected” or “coupled” to another element, it can be directly connected or coupled to the other element or intervening elements may be present. In contrast, when an element is referred to as being “directly connected or coupled” to another element, there are no intervening elements present. Furthermore, “connected” or “coupled” as used herein may include wirelessly connected or coupled. As used herein, the term “and/or” includes any and all combinations of one or more of the associated listed items.

It will be understood that, although the terms first, second, etc. may be used herein to describe various elements, these elements should not be limited by these terms. These terms are only used to distinguish one element from another. For example, a first component could be termed a second component, and, similarly, a second component could be termed a first component without departing from the teachings of the disclosure.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

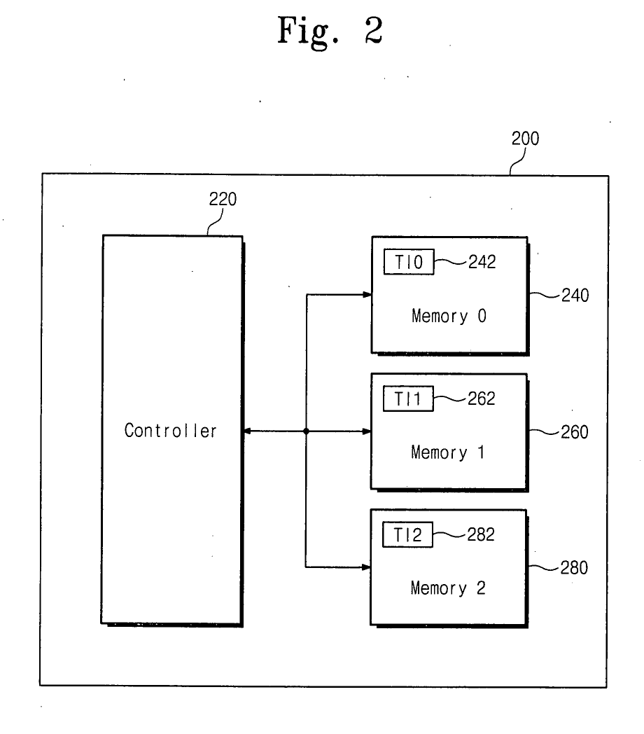

FIG. 2 illustrates a memory system 200 having a plurality of memories according to some embodiments of the present invention. Referring to FIG. 2, the memory system 200 includes a controller 220 and memories 240, 260, and 280.

The controller 220 controls each of the memories 240, 260, and 280. Each of the memories 240, 260, and 280 is connected to the controller 220 through a common bus. The controller 220 sends an instruction and an address to each of the memories 240, 260, and 280 and communicates with each of the memories 240, 260, and 280 through the common bus.

The controller 220 of the FIG. 2 embodiments accesses the memories 240, 260, and 280 using timing information (e.g., tR, tPROG, and tBERS) stored in the memories 240, 260, and 280. That is, the controller 220 of the FIG. 2 embodiments does not access the memories 240, 260, and 280 using a read and busy output (R/nB) signal that is used by a controller of a conventional memory system.

The memories 240, 260, and 280 include registers 242, 262, and 282 that store timing information. To retain the stored timing information, the memories 240, 260, and 280 are nonvolatile.

A nonvolatile memory is a memory that can retain stored data even when not powered. Examples of nonvolatile memories include, but are not limited to, a NOR flash memory, a NAND flash memory, a magnetic random access memory (MRAM), a phase change random access memory (PRAM), a resistive random access memory (ReRAM), a nano floating gate memory (NFGM), and/or a polymer random access memory (PoRAM).

In the FIG. 2 embodiments, each of the memories 240, 260, and 280 does not have an additional pin for the controller 220 to access the memories 240, 260, and 280. For example, an interrupt pin for a NOR flash memory or an R/nB pin for a NAND flash memory is not required.

For descriptive purposes, it is assumed that the memories 240, 260, and 280 are NAND flash memories. In the FIG. 2 embodiments, the memories 240, 260, and 280 need not generate R/nB signals because the controller 220 accesses the memories 240, 260, and 280 using timing information stored in the memories 240, 260, and 280 instead of unit R/nB signals. Therefore, each of the memories 240, 260, and 280 does not require an additional pin that is typically required for a memory of a conventional memory system to transmit an R/nB signal.

Each of the registers 242, 262, and 282 of the memories 240, 260, and 280 stores timing information, such as a read time tR, a programming time tPROG, and a deletion time tBERS.

The read time tR is a time necessary for loading data from a memory cell (not shown) to a page register (not shown). Data are read from a NAND flash memory using methods, such as a partial read method and/or a two plane read method. That is, data can be read from a NAND flash memory using various methods. However, the read time tR of a NAND flash memory may not vary depending on the read method used. Therefore, the controller 220 can control various read operations of the NAND flash memory using the read time tR. The controller 220 reads read time information from the registers 242, 262, and 282 of the memories 240, 260, and 280 so as not to access a memory during the read time tR of the memory.

The program time tPROG is a time necessary for programming a memory cell (not shown) using data received from a page register. Methods, such as a two plane programming method, a cache programming method, and/or a partial programming method can be used to program data into a NAND flash memory. That is, data can be programmed into a NAND flash memory using various methods. However, the programming time tPROG of a NAND flash memory may not vary depending on the programming method used. Therefore, the controller 220 can control various programming operations of the NAND flash memory using the programming time tPROG. The controller 220 reads programming time information from the registers 242, 262, and 282 of the memories 240, 260, and 280 so as not to access a memory during the programming time tPROG of the memory.

The deletion time tBERS is a time necessary for deleting data from memory cells in units of a block. The controller 220 reads deletion time information from the registers 242, 262, and 282 of the memories 240, 260, and 280 so as not to access a memory during the deletion time tBERS of the memory.

In the FIG. 2 embodiments of the present invention, the timing information is not limited to the three times tR, tPROG, and tBERS. These times tR, tPROG, and tBERS are described in the FIG. 2 embodiments because it is assumed, for purposes of illustration, that the memories 240, 260, and 280 are NAND flash memories. That is, according to various embodiments of the present invention, the timing information may vary according to the types of memories so as to allow the controller 220 to efficiently access the memories 240, 260, and 280 using the timing information.

The timing information may be stored in the registers 242, 262, and 282 after the memories 240, 260, and 280 are manufactured. The registers 242, 262, and 282 may be zero blocks (not shown) of the memories 240, 260, and 280. Generally, basic information including manufacturer, manufacturing data, and/or memory size is stored in a zero block of a memory. Therefore, when the timing information is stored in the zero blocks of the memories 240, 260, and 280, additional blocks are not required for the timing information.

In operation, the controller 220 of the memory system 200 reads the timing information from the registers 242, 262, and 282 of the memories 240, 260, and 280 and stores the timing information. Then, the controller 220 accesses the memories 240, 260, and 280 using the stored timing information.

For example, in a read process, the controller 220 accesses the memory 240 (hereinafter, referred to as a first memory) as follows: The controller 220 sends a read command to the first memory 240 and starts to count time. The first memory 240 loads corresponding data into a page buffer (not shown) in response to the read command. The controller 220 compares the counted time with the stored read time tR of the first memory 240. When the counted time is equal to or greater than the stored read time tR, the controller 220 determines that the loading of the data in the page buffer (not shown) of the first memory 240 is complete. Then, the controller 220 reads data from the page buffer of the first memory 240. In this way, the controller 220 reads data from the first memory 240.

In the memory system 200 of the FIG. 2 embodiments, the memories 240, 260, and 280 are accessed using timing information instead of using an R/nB signal. Therefore, the memories 240, 260, and 280 can be more efficiently accessed.

Access of the memories 240, 260, and 280 in the memory system 200, according to some embodiments of the present invention will now be described. For this exemplary description, the read times tRs of the memories 240, 260, and 280 are assumed to be the values set forth in the table below, and only a data reading operation is explained for clarity.

| Memory (NAND flash memory) | Read time tR |
|---|---|
| First memory 240 | 59 μs |
| Second memory 260 | 49 μs |
| Third memory 280 | 52 μs |

When the controller 220 sends a read command to each of the memories 240, 260, and 280, data loading procedures are performed. The data loading procedures may be completed in the order of the second memory 260, the third memory 280, and the first memory 240. The controller 220 of the FIG. 2 embodiments does not check the statuses of the memories 240, 260, and 280 before the controller 220 accesses the memories 240, 260, and 280. Instead, the controller 220 accesses the memories 240, 260, and 280 using information about the read times tRs of the memories 240, 260, and 280. After data is loaded to the register 262 of the second memory 260 in 49 μs, the controller 220 can access the second memory 260. In other words, the controller 220 can access the second and third memories 260 and 280 before data is completely loaded to the register 242 of the first memory 240.

In a conventional memory system, memories (e.g., first to third memories) are typically sequentially accessed using an R/nB signal. Therefore, until data loading of the first memory is completed, the second or third memory cannot be accessed although data loading of the second or third memory is completed. However, in some embodiments of the present invention, the controller 220 has information about the read times tRs of the memories 240, 260, and 280. Therefore, the controller 220 can determine whether data loading of the second or third memory 260 or 280 is completed by using the read time tR of the second or third memory 260 or 280, and, thus, the controller 220 can perform the next operation on the second or third memory 260 or 280 regardless of whether data loading of the first memory 240 is completed.

In the memory system 200 of the FIG. 2 embodiments, the memories 240, 260, and 280 can be more efficiently accessed using information about the read times tRs of the memories 240, 260, and 280.

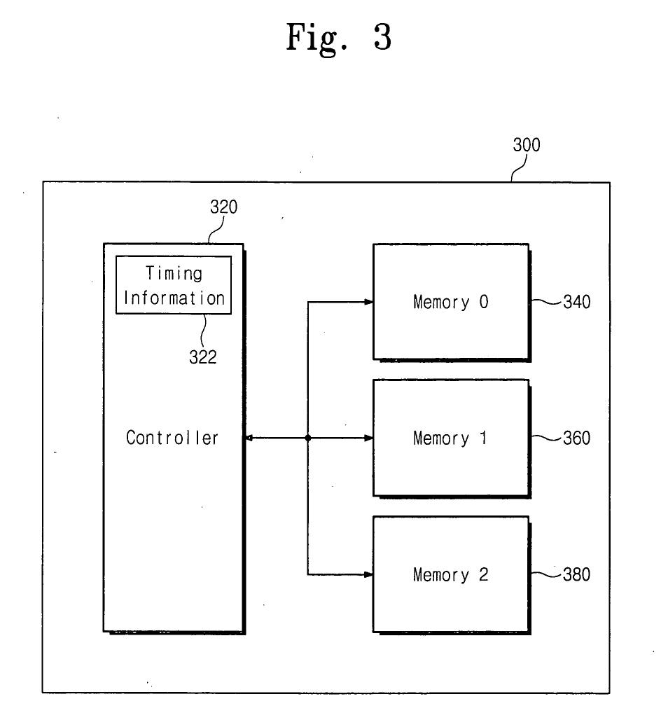

FIG. 3 illustrates a memory system 300 having a plurality of memories according to further embodiments of the present invention. Referring to FIG. 3, the memory system 300 includes a controller 320 and memories 340, 360, and 380. In the FIG. 3 embodiments, the controller 320 stores timing information of the memories 340, 360, and 380 (e.g., tR, tPROG, and tBERS). The controller 320 accesses the memories 340, 360, and 380 using the stored timing information.

Unlike the memories 240, 260, and 280 of the memory system 200 of FIG. 2, the memories 340, 360, and 380 of the memory system 300 do not store their timing information. Instead, the memories 340, 360, and 380 generate R/nB signals.

In operation, the controller 320 receives an R/nB signal from each of the memories 340, 360, and 380 to obtain timing information using the R/nB signal. The timing information of the memories 340, 360, and 380 is stored in a timing information register 322 of the controller 320. After that, the controller 320 accesses the memories 340, 360, and 380 using the timing information stored in the timing information register 322 instead of using an R/nB signal. That is, no R/nB signal is used except for initialization.

In the FIG. 3 embodiment, the memories 340, 360, and 380 can be volatile or nonvolatile because timing information used for accessing the memories 340, 360, and 380 is stored in the timing information register 322.

In the memory system 300 of the FIG. 3 embodiments, the timing information register 322 stores timing information necessary for accessing the memories 340, 360, and 380. That is, in the memory system 300, the memories 340, 360, and 380 are accessed using the timing information stored in the timing information register 322. Therefore, the memories 340, 360, and 380 can be accessed more efficiently than memories of a conventional memory system.

The memory systems 200 and 300 of the embodiments of the present invention may be multi-chip memory systems or one-chip memory systems. Furthermore, each of the memory systems 200 and 300 can be mounted on a single substrate.

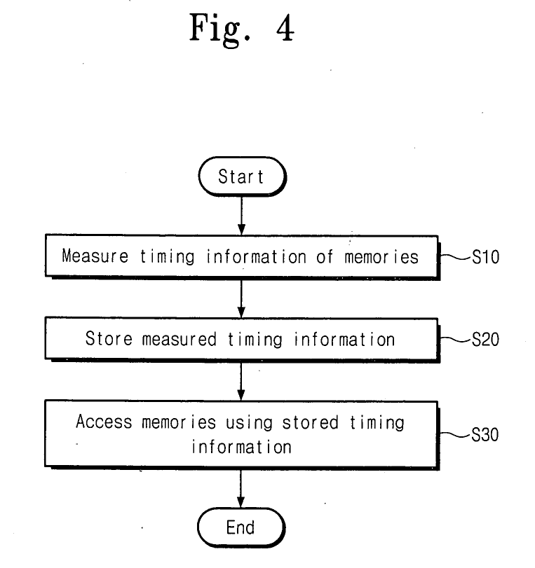

FIG. 4 illustrates methods of accessing a plurality of memories of a memory system according to some embodiments of the present invention. Referring to FIG. 4, operations begin with operation S10 where timing information of a plurality of memories is measured. The timing information includes times necessary for a controller to access the memories. For example, when the memories are NAND flash memories, the timing information may include a read time tR, a programming time tPROG, and/or a deletion time tBERS. The timing information may be measured using different methods depending on whether the memory system is the memory system 200 of FIG. 2 or the memory system 300 of FIG. 3.

In the case where the memory system is the memory system 200 of FIG. 2, the memories 240, 260, and 280 of the memory system 200 include the registers 242, 262, and 282 that store timing information. Therefore, in operation S10, the controller 220 measures the timing information of the memories 240, 260, and 280 by reading the timing information from the registers 242, 262, and 282 of the memories 240, 260, and 280.

Meanwhile, in the case where the memory system is the memory system 300 of FIG. 3, the controller 320 of the memory system 300 stores the timing information. The controller 320 includes the timing information register 322 for storing the timing information. Therefore, in operation S10, the controller 320 receives R/nB signals from the memories 340, 360, and 380 to measure the timing information of the memories 340, 360, and 380.

In operation S20, the timing information measured in operation S 10 is stored. Both the controllers 220 and 320 of FIGS. 2 and 3 store the timing information.

In operation S30, the controller accesses the memories using the timing information stored in operation S20. In the case of the memory system 200 of FIG. 2, no R/nB signal is used for the controller 220 to access the memories 240, 260, and 280. In the case of the memory system 300 of FIG. 3, R/nB signals are used only when the controller 320 initially measures the timing information of the memories 340, 360, and 380, and after that, the controller 320 accesses the memories 340, 360, and 380 using the measured timing information without using any R/nB signal.

The memory system according to some embodiments of the present invention can be used in a memory card.

The memory system 200 of the embodiments illustrated in FIG. 2 does not use any R/nB signal for accessing the memories 240, 260, and 280, such that the memories 240, 260, and 280 do not have R/nB pins. Therefore, the memory system 200 can be packaged in a relatively small size. In the case of the memory system 300 of the embodiments illustrated in FIG. 3, R/nB signals are used only for initialization. That is, only in initial operation are R/nB signals transmitted from the memories 340, 360, and 380 to the controller 320 by sharing other pins, and then, R/nB pins may not necessary.

As described above, in the memory systems and the memory access methods thereof according to some embodiments of the present invention, the controller accesses the memories using the timing information of the memories. Therefore, according to some embodiments of the present invention, memories can be accessed more efficiently.

The above-disclosed subject matter is to be considered illustrative, and not restrictive, and the appended claims are intended to cover all such modifications, enhancements, and other embodiments, which fall within the true spirit and scope of the present invention. Thus, to the maximum extent allowed by law, the scope of the present invention is to be determined by the broadest permissible interpretation of the following claims and their equivalents, and shall not be restricted or limited by the foregoing detailed description.

That which is claimed:

1. A memory system comprising:
a plurality of memories; and
a controller configured to control the memories and to access each of the memories using timing information respectively associated with each of the memories.

2. The memory system of claim 1, wherein the memories comprise registers that store the timing information, respectively.

3. The memory system of claim 2, wherein the memories share a common bus line.

4. The memory system of claim 2, wherein the controller accesses the memories using the timing information read from the registers in an initializing operation.

5. The memory system of claim 2, wherein the memories are configured to not generate R/nB (ready and busy output) signals.

6. The memory system of claim 2, wherein the memories are nonvolatile memories.

7. The memory system of claim 6, wherein the memories are NAND flash memories.

8. The memory system of claim 7, wherein the timing information comprises a read time tR, a programming time tPROG, and a deletion time tBERS.

9. The memory system of claim 8, wherein the registers are respectively defined using zero blocks of the memories that store basic information of the memories.

10. The memory system of claim 8, wherein the controller comprises a storage that stores the timing information read from the registers of the memories.

11. The memory system of claim 10, wherein the controller accesses the memories using the timing information stored in the storage.

12. The memory system of claim 1, wherein the memory system is a multi-chip memory system or a one-chip memory system.

13. A memory system, comprising:
a plurality of memories; and
a controller configured to control the memories and to store timing information respectively associated with each of the memories that is used to access the memories.

14. The memory system of claim 13, wherein the controller comprises a register that stores the timing information.

15. The memory system of claim 14, wherein the memories share a common bus line.

16. The memory system of claim 14, wherein the controller is configured to measure the timing information using R/nB signals received from the memories and to store the measured timing information in the register in an initializing operation.

17. The memory system of claim 16, wherein the controller is configured to ignore R/nB signals transmitted from the memories after the timing information is stored in the register of the controller.

18. The memory system of claim 17, wherein the memories are nonvolatile memories.

19. The memory system of claim 18, wherein the memories are NAND flash memories.

20. The memory system of claim 19, wherein the timing information comprises a read time tR, a programming time tPROG, and a deletion time tBERS.

21. The memory system of claim 13, wherein the memory system is a multi-chip memory system or a one-chip memory system.

22. A method of accessing a memory system that includes a plurality of memories and a controller that controls the memories, the method comprising:
measuring timing information associated with each of the memories;
storing the measured timing information; and
accessing the memories using the stored timing information.

23. The method of claim 22, wherein measuring of the timing information comprises reading timing information stored in the memories.

24. The method of claim 23, wherein the timing information comprises information stored in the memories when the memories are manufactured.

25. The method of claim 24, wherein the controller comprises a timing information register configured to store the measured timing information.

26. The method of claim 25, wherein the memories are nonvolatile memories.

27. The method of claim 26, wherein the memories are NAND flash memories.

28. The method of claim 27, wherein the timing information comprises a read time tR, a programming time tPROG, and a deletion time tBERS.

29. The method of claim 22, wherein measuring the timing information comprises operating the controller to measure the timing information using R/nB signals received from the memories in an initializing operation.

30. The method of claim 29, wherein storing the measured timing information comprises storing the measured timing information in a timing information register in the controller.

31. The method of claim 30, further comprising after storing the measured timing information in the timing information register:
ignoring R/nB signals transmitted from the memories; and
accessing the memories using the measured timing information stored in the timing information register.

32. The method of claim 22, wherein the memory system is a memory card.
